(19) United States
(12) Patent Application Publication
(10) Pub. No.: US 2025/0180981 A1
(43) Pub. Date: Jun. 5, 2025

(54) MASK AND METHOD OF MANUFACUTING THE SAME

(71) Applicant: Samsung Display Co., LTD., Yongin-si (KR)

(72) Inventors: JINWOO LEE, Yongin-si (KR); JEONGKUK KIM, Yongin-si (KR); DUCKJUNG LEE, Yongin-si (KR); SUGWOO JUNG, Yongin-si (KR); SUNGWON CHO, Yongin-si (KR); JUNHO JO, Yongin-si (KR)

(21) Appl. No.: 18/937,569

(22) Filed: Nov. 5, 2024

(30) Foreign Application Priority Data
Dec. 1, 2023 (KR) 10-2023-0172674

(51) Int. Cl. G03F 1/42; C23C 14/04; G03F 1/80; H10K 71/10

(52) U.S. Cl. CPC G03F 1/42; C23C 14/042; G03F 1/80; H10K 71/191

(57) ABSTRACT

A mask includes a frame in which at least one first opening defined in a center portion of the frame and at least one second opening defined in an edge portion of the frame are defined, a first mask sheet disposed on the frame, and in which a plurality of deposition openings each overlapping the first opening is defined, and a second mask sheet surrounding at least a portion of the first mask sheet on the frame, and including a different material from a material of the first mask sheet.

This application claims priority to Korean Patent Application No. 10-2023-0172674, filed on Dec. 1, 2023, and all the benefits accruing therefrom under 35 U.S.C. § 119, the content of which in its entirety is herein incorporated by reference.

### BACKGROUND

### 1. Field

Embodiments relate to a mask and a method of manufacturing the same. More particularly, embodiments relate to the mask used in a deposition process and the method of manufacturing the same.

### 2. Description of the Related Art

A display device displays images to provide visual information to users. The display device includes a liquid crystal display, a light-emitting diode display, an organic light-emitting diode display, and a quantum dot display.

A mask may be used to manufacture the display device. The mask may be fixed to a desired location on a substrate included in the display device. Deposition materials are sprayed toward the fixed mask and substrate, and passes through deposition openings defined in the mask to form a component (e.g., a light-emitting layer) of the display device.

### SUMMARY

Embodiments provide a mask that controls a deformation of a frame.

Embodiments provide a method of manufacturing the mask.

A mask in an embodiment of the disclosure includes a frame in which at least one first opening defined in a center portion of the frame and at least one second opening defined in an edge portion of the frame are defined, a first mask sheet which is disposed on the frame, and in which a plurality of deposition openings each overlapping the first opening is defined, and a second mask sheet surrounding at least a portion of the first mask sheet on the frame, and including a different material from a material of the first mask sheet.

In an embodiment, the second mask sheet may directly contact the edge portion of the frame.

In an embodiment, the first mask sheet may include a magnetic material.

In an embodiment, the first mask sheet may include a first conductive layer and a second conductive layer disposed on the first conductive layer.

In an embodiment, the first conductive layer may include at least one of a titanium (Ti) and a titanium nitride (TiN), and the second conductive layer may include at least one of cobalt (Co) and a nickel (Ni).

In an embodiment, the mask may further include an alignment portion disposed on the frame, adjacent to the second mask sheet, and in which an alignment mark is defined, and the alignment portion may include a same material as that of the first conductive layer.

In an embodiment, the alignment mark may overlap the second opening.

In an embodiment, the alignment portion may include a first layer corresponding to the first conductive layer and a second layer disposed on the first layer and corresponding to the second conductive layer, and the first layer may include a same material as that of the first conductive layer, and the second layer may include a same material as that of the second conductive layer.

In an embodiment, the alignment portion may be spaced apart from the first mask sheet.

In an embodiment, a portion of the first mask sheet disposed between two deposition openings adjacent to each other among the plurality of deposition openings may have an inverse tapered shape in a cross-sectional view.

In an embodiment, a plurality of dummy openings penetrating the second mask sheet in a thickness direction may be defined in the second mask sheet.

In an embodiment, a portion of the second mask sheet disposed between two dummy openings adjacent to each other among a plurality of dummy openings may have a tapered shape in the cross-sectional view.

A method of manufacturing a mask in an embodiment of the disclosure includes forming a preliminary mask sheet on a preliminary frame including a center area and an edge area adjacent to the center area, forming a first preliminary conductive layer on the preliminary mask sheet, forming a second preliminary conductive layer on at least a portion of the first preliminary conductive layer, forming a frame in which at least one first opening defined in the center area and at least one second opening defined in the edge area are defined by removing a portion of the preliminary frame, forming a first mask sheet in which a plurality of deposition openings area is defined by removing a portion of each of the first preliminary conductive layer and the second preliminary conductive layer in the center area, and forming a second mask sheet in which a plurality of dummy openings is defined by removing a portion of the first preliminary conductive layer in the edge area.

In an embodiment, the method may further include forming an alignment portion in which an alignment mark is defined by removing a portion of the first preliminary conductive layer in the edge area.

In an embodiment, the forming the alignment portion and the forming the second mask sheet may be performed by a same process.

In an embodiment, the method may further include forming an alignment pattern in the edge area of the preliminary frame and covering the alignment pattern by the preliminary mask sheet, and the forming the alignment pattern and the covering the alignment pattern may be performed before the forming the preliminary mask sheet.

In an embodiment, the second preliminary conductive layer may overlap the alignment pattern in a plan view.

In an embodiment, the method may further include removing the alignment pattern and forming an alignment portion in which an alignment mark is defined in an area corresponding to the alignment pattern by removing each of the first preliminary conductive layer and the second preliminary conductive layer.

In an embodiment, forming the removing the alignment pattern and the forming the frame may be performed simultaneously.

In an embodiment, the forming the second preliminary conductive layer may include flattening the second preliminary conductive layer so that an upper surface of the second preliminary conductive layer may be substantially flat and aligned with an upper surface of the first preliminary conductive layer.

In the mask in embodiments, the mask may include a frame in which a first opening defined in a center portion of the mask and the second opening defined in an edge portion of the mask are defined, a first mask sheet which is disposed on the frame and in which a plurality of deposition openings is defined, and a second mask sheet surrounding at least a portion of the first mask sheet. In addition, the second mask sheet may contact an edge portion of the frame. Accordingly, in a deposition process using the mask, the second mask sheet may distribute a bonding force applied to the center portion of the frame to the edge portion of the frame in which the second mask sheet is disposed. Accordingly, the center portion of the frame from bending toward a substrate during the deposition process may be prevented, and precision and uniformity of the deposition process may be improved.

In the method of manufacturing the mask in embodiments of the disclosure, in a center area of a preliminary mask sheet, the first mask sheet may be formed as first preliminary conductive layer and second preliminary conductive layer filling an opening defined in the preliminary mask sheet are removed. In addition, in an edge area of the preliminary mask sheet, the second mask sheet may be formed as a portion of the preliminary mask sheet is not removed in an etching process. Accordingly, process time and cost of a manufacturing process of the mask may be reduced

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an embodiment of a mask according to the disclosure.

FIG. 2 is an exploded perspective view illustrating the mask of FIG. 1 disassembled.

FIG. 3 is a cross-sectional view illustrating a deposition process using the mask of FIG. 1.

FIG. 4 is a plan view illustrating the mask of FIG. 1.

FIG. 5 is an enlarged plan view illustrating an area A of FIG. 4.

FIG. 6 is a cross-sectional view illustrating an embodiment of a cross-section taken along line I-I′ of FIG. 1.

FIGS. 7, 8, 9, 10, 11, 12, 13, 14, 15, 16, and 17 are cross-sectional views illustrating an embodiment of a method of manufacturing the mask of FIG. 1.

FIG. 18 is a cross-sectional view illustrating another embodiment of a cross-section taken along line I-I′ of FIG. 1.

FIG. 19 is an enlarged plan view illustrating an area B of FIG. 19.

FIGS. 20, 21, 22, 23, 24, 25, and 26 are cross-sectional views illustrating another embodiment of a method of manufacturing the mask of FIG. 1.

### DETAILED DESCRIPTION

Hereinafter, display devices in embodiments will be described in more detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

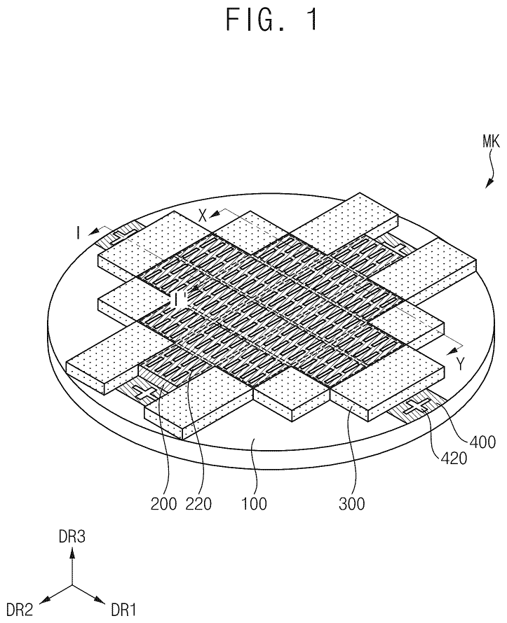

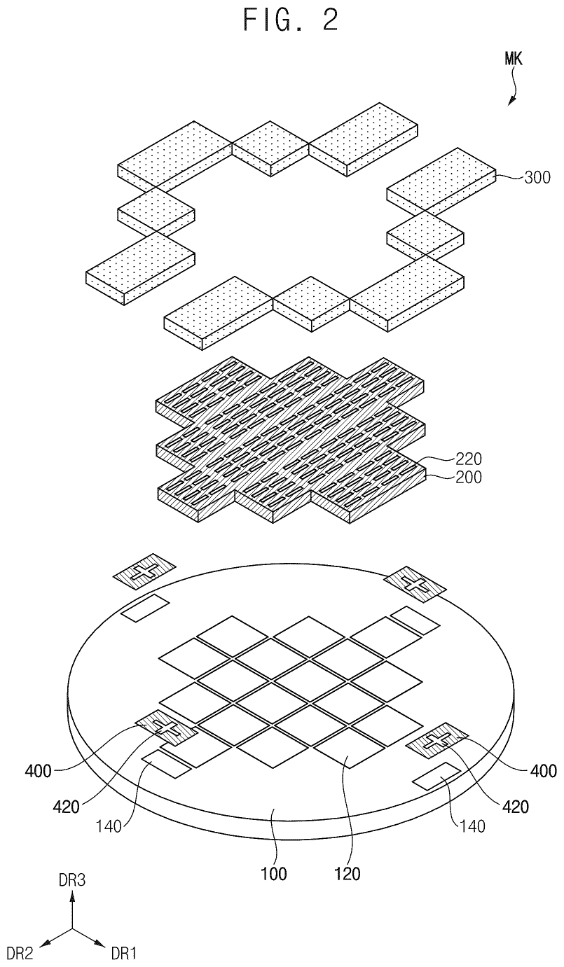

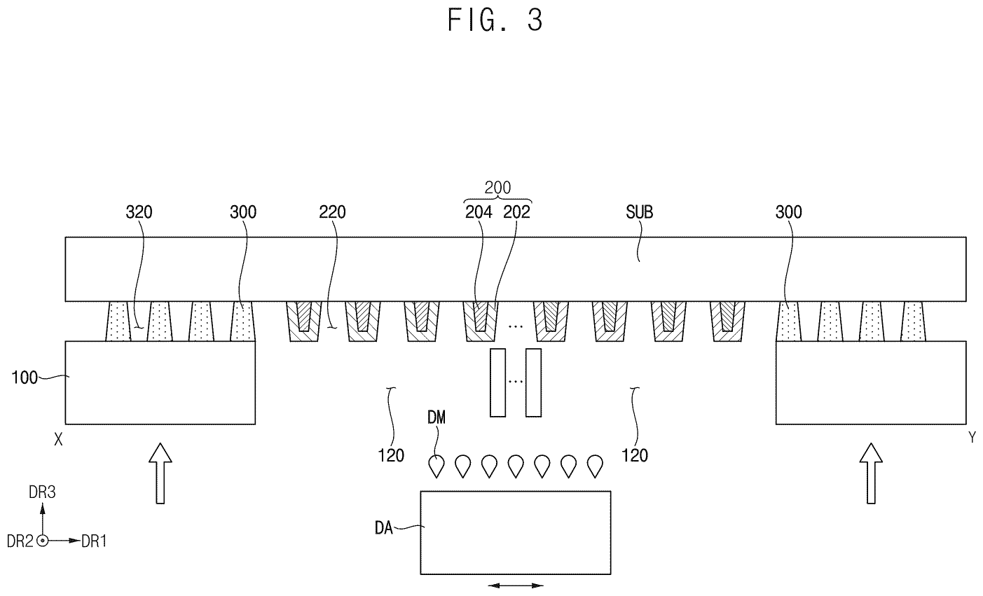

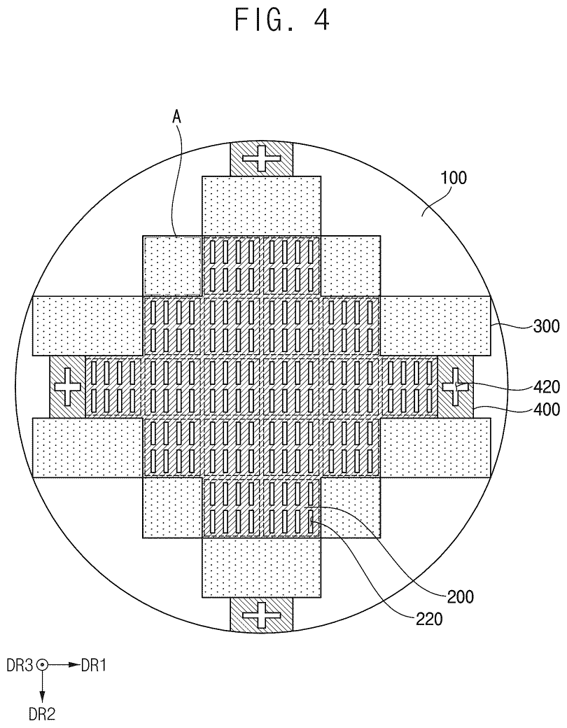

FIG. 1 is a perspective view illustrating an embodiment of a mask according to the disclosure. FIG. 2 is an exploded perspective view illustrating the mask of FIG. 1 disassembled. FIG. 3 is a cross-sectional view illustrating a deposition process using the mask of FIG. 1. FIG. 4 is a plan view illustrating the mask of FIG. 1. For example FIG. 3 is a cross-sectional view illustrating a mask MK of FIG. 1 taken along line X-Y and other components (e.g., a substrate SUB and a deposition apparatus DA).

Referring to FIGS. 1, 2, 3, and 4, a mask MK in an embodiment of the disclosure may include a frame 100, a first mask sheet 200, a second mask sheet 300, and an alignment portion 400. The mask MK may be used in a process manufacturing a display device. In an embodiment, the mask Mk may be a deposition mask to deposit deposition materials on a substate SUB, for example. The deposition materials DM may be a material (e.g., an organic light-emitting material) forming a light-emitting layer which emits a light in the display device.

In this specification, a plane may be defined by a first direction DR1 and a second direction DR2 intersecting with the first direction DR1. In an embodiment, the first direction DR1 and the second direction DR2 may be perpendicular to each other, for example. In addition, the third direction (also referred to as a thickness direction) DR3 may be perpendicular to the plane.

The frame 100 may be parallel to the first direction DR1 and the second direction DR2. The frame 100 may have a circular shape in a plan view. However the disclosure may not be limited to this, the frame 100 may have a polygonal shape in a plan view. In an embodiment, the frame 100 may include a silicon wafer.

At least one first opening 120 and at least one second opening 140 may be defined in the frame 100. The first and second openings 120 and 140 may penetrate the frame 100 in the third direction DR3.

The first opening 120 may be defined in a center portion of the frame 100. A plurality of first openings 120 may be arranged along the first direction DR1 and second direction DR2. A shape of first opening 120 may be a quadrangle (e.g., square) in a plan view. However, the disclosure may not be limited to this, the first opening 120 may have a various shape in a plan view.

The second opening 140 may be disposed in an edge portion of the frame 100. A size of the second opening 140 may be different from a size of the first opening 120. However, the disclosure may not be limited to this.

The first mask sheet 200 may be disposed on the first frame 100. The first mask sheet 200 may be disposed to correspond to the first opening 120. The first mask sheet 200 may overlap the first opening 120. In addition, the first mask sheet 200 may contact a portion of the frame 100 adjacent to the first opening 120. Accordingly, the first mask sheet 200 may overlap the first opening 120 defined in the frame 100 entirely, and be fixed on the frame 100.

The first mask sheet 200 may include a first conductive layer 202 and a second conductive layer 204. The second conductive layer 204 may be disposed on the first conductive layer 202. In an embodiment, the second conductive layer 204 may cover a rear surface and a side surface of the first conductive layer 202, for example.

In an embodiment, each of the first conductive layer 202 and the second conductive layer 204 may include a metal material. In an embodiment, the first conductive layer 202 and the second conductive layer 204 may include a different material from each other. In an embodiment, the first conductive layer 202 may include a titanium (Ti), a titanium nitride (TiN), or the like, for example. These may be used in alone or in a combination with each other. In addition, the second conductive layer 204 may include a cobalt (Co), and a nickel (Ni), or the like. These may be used in alone or in any combinations with each other.

In an embodiment, the first mask sheet 200 may include a magnetic material. In a case that the first mask sheet 200 includes the magnetic material, the mask MK may combined with the substrate SUB by a magnetic force generated between the mask MK and the substrate SUB. In an embodiment, the mask MK and the substrate SUB may be combined with a electrostatic chuck (“ESC”), for example. Specifically, a pressure plate including the electrostatic chuck may be disposed another side of the substrate SUB opposite to the one side facing the mask MK. Accordingly, when the mask MK is coupled to the substrate SUB, a precision of combining the mask MK may be improved, and the display device with relatively high resolution may be manufactured.

A plurality of deposition openings 220 penetrating the first mask sheet 200 in a third direction DR3 may be defined in the first mask sheet 200. The deposition openings 220 may be arranged along the first and second directions DR1 and DR2. The deposition openings 220 may overlap the first opening 120. In an embodiment, a size of each of the deposition openings 220 may be smaller than a size of each of the first opening 120.

In an embodiment, a portion of the first mask sheet 200 disposed between two deposition openings 220 adjacent to each other among the plurality of deposition openings 220 may have an inverse tapered shape in a cross-sectional view. Specifically, the first conductive layer 202 and the second conductive layer 204 disposed between the two deposition openings 220 adjacent to each other may have a tapered shape together in a cross-sectional view. However, the disclosure may not be limited to this.

In an embodiment, an average width of each of the deposition openings 220 in a first direction DR1 or in a second direction DR2 may decrease toward the third direction DR3. In another embodiment, the average width of each of the deposition openings 220 may increase toward the third direction DR3. In another embodiment, the average width of each of the deposition openings 220 may be substantially same toward the third direction DR3.

The deposition materials DM may penetrate the first mask sheet 200 through the deposition openings 220. Specifically, the deposition materials DM sprayed from the deposition apparatus DA to the mask MK may penetrate the first opening 120 and the deposition openings 220 and may be deposited on the substrate SUB. Each of the deposition openings 220 may have various shape and structure according to a location of the substrate SUB on which the deposition materials DM are deposited.

The second mask sheet 300 may be disposed on the frame 100. Dummy openings 320 penetrating the second mask sheet 300 in the third direction DR3 may be defined in the second mask sheet 300. The dummy openings 320 may be disposed along the first and second directions DR1 and DR2. In an embodiment, the second mask sheet 300 may have a tapered shape in a cross-sectional view. However, the disclosure may not be limited to this.

In an embodiment, an average width of the dummy openings 320 in the first direction DR1 or in the second direction DR2 may increase toward third direction DR3. In another embodiment, the average width of the dummy openings 320 may decrease toward the third direction DR3. In another embodiment, the average width of the dummy openings 320 may substantially same toward the third direction DR3.

In an embodiment, the second mask sheet 300 may contact an edge portion of the frame 100. In addition, the second mask sheet 300 may surround at least a portion of the first mask sheet 200. Accordingly, the second mask sheet 300 may distribute a bonding force applied to the center portion of the frame to the edge portion of the frame 100 on which the second mask sheet 300 disposed. Accordingly, a phenomenon which the center portion of the frame 100 is bent toward the substrate SUB during the deposition process may be prevented, and precision and uniformity of the deposition process may be improved.

In an embodiment, the second mask sheet 300 may include a different material from the first mask sheet 200. The second mask sheet may include an inorganic material. In an embodiment, the inorganic material may include a silicon (Si), a silicon nitride (SiNₓ), a silicon oxide (SiOₓ), a silicon oxynitride (SiNₓO_{y}), or the like, for example. These may be used in alone or in any combinations with each other.

The alignment portion 400 may disposed on the frame 100. The alignment portion 400 may overlap the second opening 140. In addition, the alignment portion 400 may be disposed adjacent to the second mask sheet 300.

At least one of the alignment portion 400 may be disposed. In an embodiment, a plurality (e.g. a number of the alignment portion 400 is two or more) of the alignment portions 400 may be disposed, for example. Specifically, a portion among the plurality of the alignment portions 400 may be spaced apart from the first mask sheet 200, and be adjacent to the second mask sheet 300. In addition, another portion among the plurality of the alignment portions 400 may be adjacent to each of the first mask sheet 200, and the second mask sheet 300. However, a location of the alignment portion 400 may not be limited to this, and the alignment portion 400 may have various arrangement and number.

An alignment mark 420 penetrating the alignment portion 400 in the third direction DR3 may be defined in the alignment portion 400. The alignment mark 420 may be a hole having a predetermined shape in a plan view.

The alignment portion 400 may adjust the first mask sheet 200 to be disposed on a predetermined location of the substrate SUB. Specifically, the alignment mark 420 may be combined with an alignment pattern of the substate SUB disposed in a predetermined location of the substate SUB, so that a location of the deposition openings 220 defined in the first mask sheet 200 may be correspond to the predetermined location of the substrate SUB.

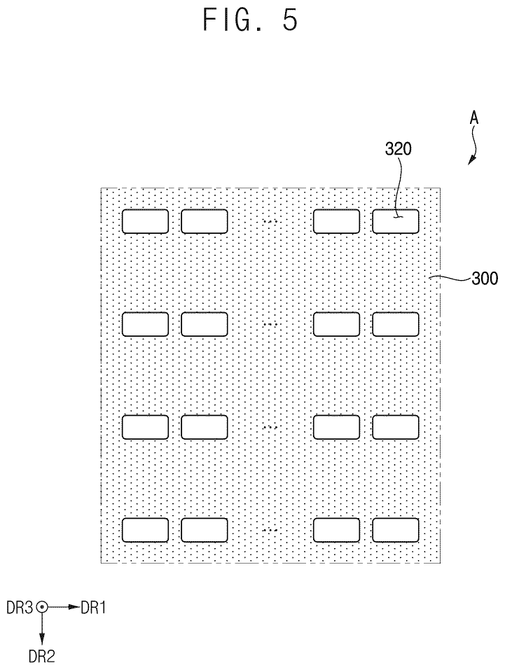

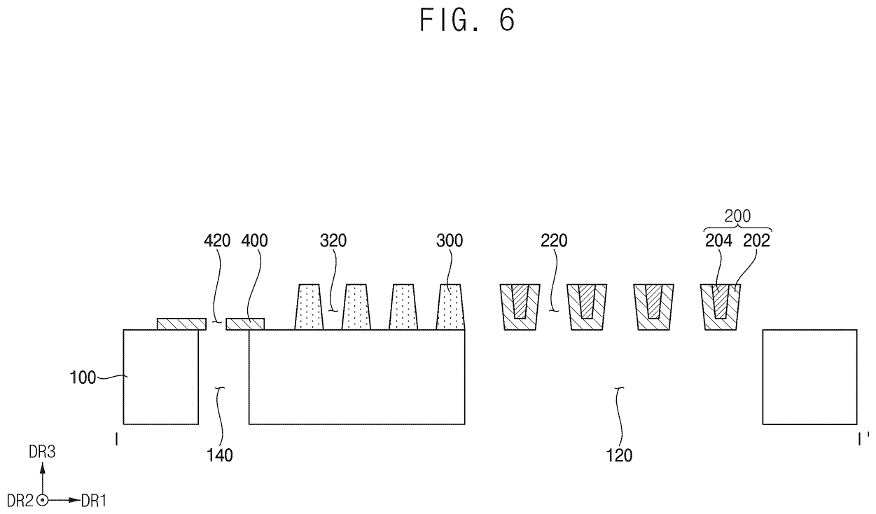

FIG. 5 is an enlarged plan view illustrating an area A of FIG. 4. FIG. 6 is a cross-sectional view illustrating an embodiment of a cross-section taken along line I-I′ of FIG. 1. In an embodiment, FIG. 5 is an enlarged view illustrating the second mask sheet 300 included in the mask MK, for example.

Referring to FIGS. 5 and 6, the alignment portion 400 may include a same material as that of the first conductive layer 202. The alignment portion 400 may be formed through a same process as the first conductive layer 202. In an embodiment, the alignment portion 400 may include titanium (Ti), titanium nitride (TiN), or the like, for example. These may be used in alone or in any combinations with each other.

The alignment mark 420 may overlap the second opening 140. In an embodiment, a width of the alignment mark 420 in the first direction DR1 may be smaller than a width of the second opening 140 in the first direction DR1, for example. The alignment mark 420 is defined as a hole exposing the second opening 140 and may be connected to the second opening 140.

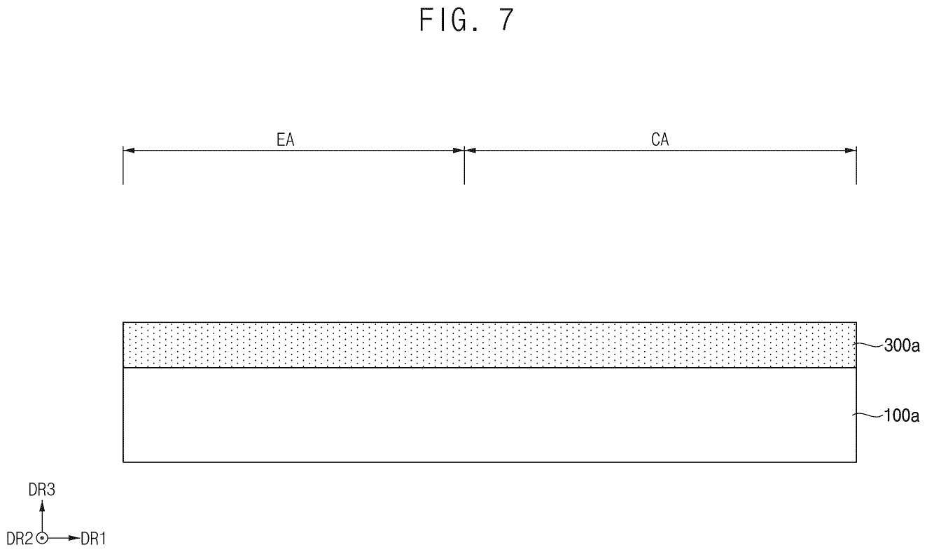

FIGS. 7, 8, 9, 10, 11, 12, 13, 14, 15, 16, and 17 are cross-sectional views illustrating an embodiment of a method of manufacturing the mask of FIG. 1.

FIG. 7 is a cross-sectional view illustrating a cross-section of each portion of a preliminary frame 100a and a preliminary mask sheet 300a disposed corresponding to the line I-I′ of FIG. 1.

Referring to FIG. 7, a preliminary frame 100a may include a center area CA and an edge area EA. The center area CA may be correspond to an area where the first mask sheet (e.g., the first mask sheet 200 of FIG. 1) is formed on the frame (e.g. the frame 100 of FIG. 1). The edge area EA may be an area adjacent to the center area CA. The edge area EA may be an area adjacent to a side of the preliminary frame 100a disposed on the outside of the preliminary frame 100a.

The preliminary mask sheet 300a may be formed on the preliminary frame 100a. In an embodiment, the preliminary mask sheet 300a may overlap the center area CA and the edge area EA of the preliminary frame 100a, for example.

The preliminary frame 100a may include a silicon wafer. The preliminary mask sheet 300a may include an inorganic material. In an embodiment, the inorganic material may include a silicon (Si), a silicon nitride (SiNₓ), a silicon oxide (SiOₓ), a silicon oxynitride (SiNₓO_{y}), or the like. These may be used in alone or in any combinations with each other, for example.

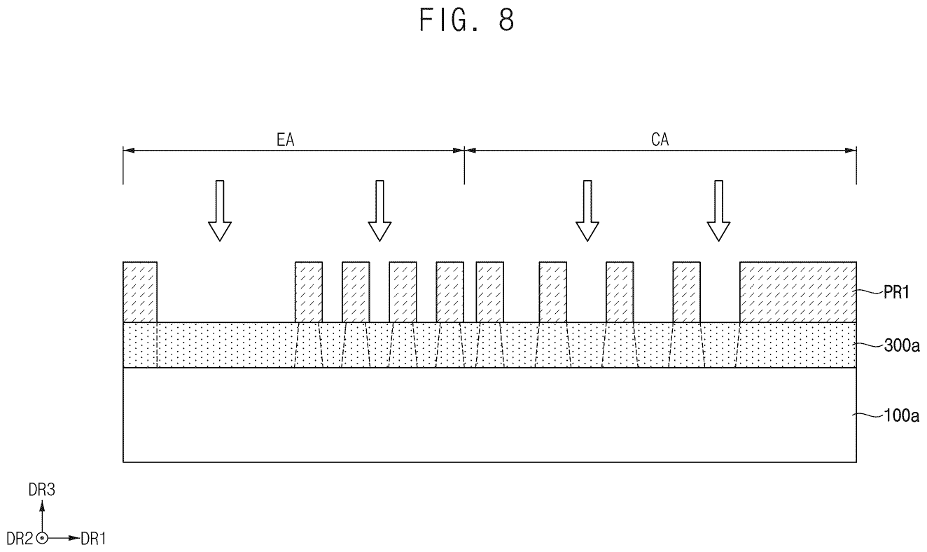

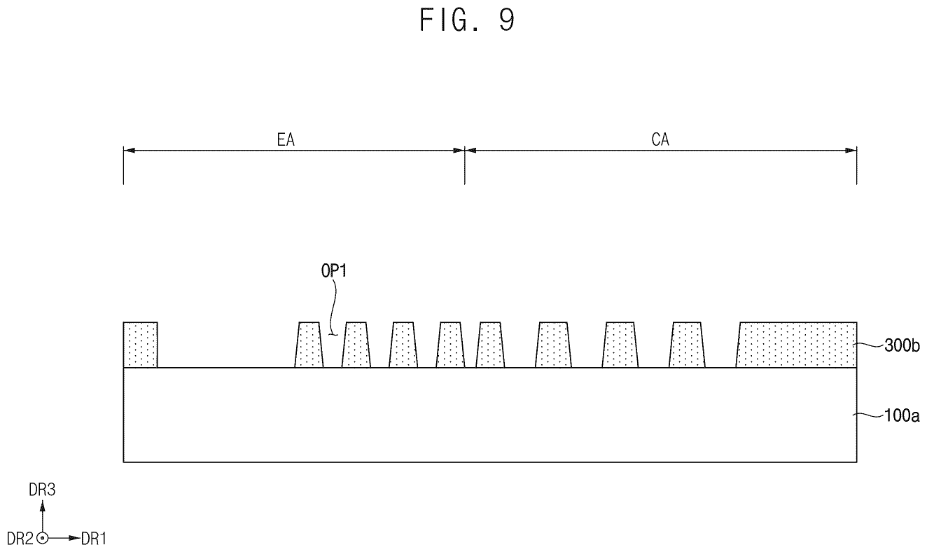

Referring to FIGS. 8 and 9, a photoresist PR1 may formed on the preliminary mask sheet 300a. Specifically, the photoresist PR1 may be formed to correspond to a predetermined location of the preliminary mask sheet 300a. The photoresist PR1 may be formed in a predetermined location in each of the center area CA and the edge area EA on the preliminary mask sheet 300a. In an embodiment, the predetermined location may be a location where the preliminary mask sheet 300b of FIG. 9 is formed. In an alternative embodiment, the predetermined location may be a location where a plurality of openings OP1 is defined.

After the photoresist PR1 is formed, a light may be irradiated into the preliminary mask sheet 300a and the photoresist PR1. When the light is irradiated, a portion of the preliminary mask sheet 300a may be removed.

In an embodiment, the photoresist PR1 may include a positive photoresist. In a case that the photoresist PR1 includes the positive photoresist, a portion of the preliminary mask sheet 300a which does not overlap with the photoresist PR1 may be removed. In an alternative embodiment, the photoresist PR1 may include a negative photoresist. In a case that the photoresist PR1 may include the negative photoresist, a portion of the preliminary mask sheet 300a which overlaps the photoresist PR1 may be removed.

A portion of the preliminary mask sheet 300a may be removed to form a preliminary mask sheet 300b with the plurality of openings OP1 defined. The preliminary mask sheet 300b of FIG. 9 may be a mask sheet in which a portion of the preliminary mask sheet 300a of FIG. 8 is removed.

The openings OP1 may penetrate the preliminary mask sheet 300b in the third direction DR3. A portion of an upper surface of the preliminary frame 100a may be exposed through the openings OP1. In an embodiment, a width of each of the openings OP1 in the first direction DR1 may be different. However, the disclosure may not be limited to this.

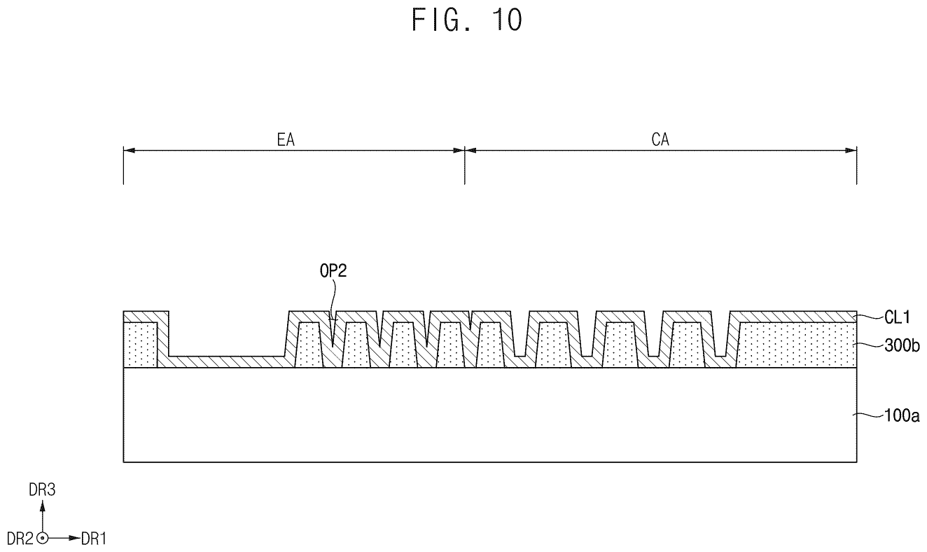

Referring to FIG. 10, a first preliminary conductive layer CL1 may be formed on the preliminary mask sheet 300b. Specifically, the first preliminary conductive layer CL1 may fill the openings OP1 and cover upper and side surfaces of the preliminary mask sheet 300b. In an embodiment, the first preliminary conductive layer CL1 may include titanium (Ti), titanium nitride (TiN), or the like. These may be used in alone or in any combinations with each other.

Openings OP2 corresponding to the openings OP1 may be defined in the first preliminary conductive layer CL1. Each of the openings OP2 may be defined to correspond to each of the openings OP1. As the openings OP1 are filled with the first preliminary conductive layer CL1, the width of the openings OP2 in the first direction DR1 becomes smaller than the width of the openings OP1 in the first direction DR1.

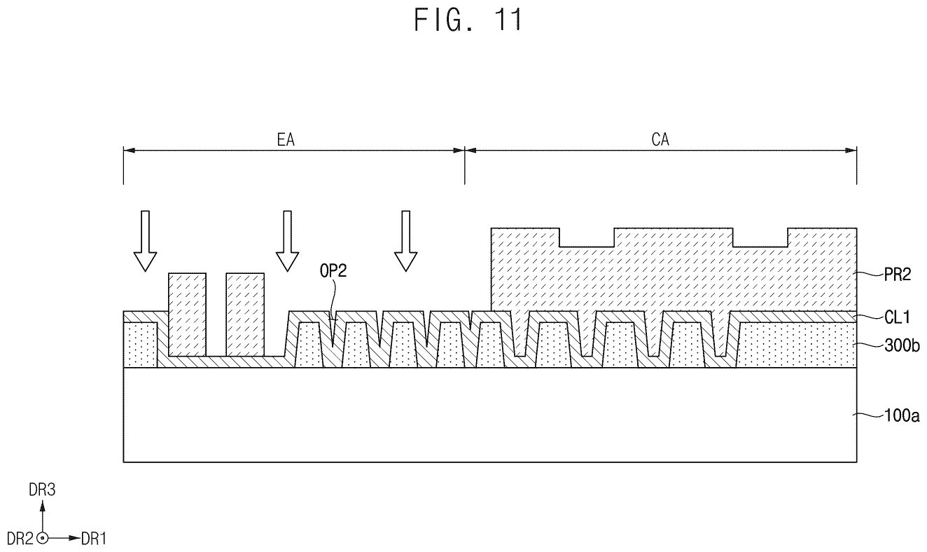

Referring to FIG. 11, a photoresist PR2 may be formed in the first preliminary conductive layer CL1. The photoresist PR2 may be disposed to correspond to a predetermined location of the first preliminary conductive layer CL1. After the photoresist PR2 is formed, a light may be irradiated into the first preliminary conductive layer CL1. As the light is irradiated, a portion of the first preliminary conductive layer CL1 may be removed.

In an embodiment, the photoresist PR2 may include a positive photoresist. In a case that the photoresist PR2 includes the positive photoresist, a portion of the first preliminary conductive layer CL1 that does not overlap the photoresist PR2 may be removed. In an alternative embodiment, the photoresist PR2 may include a negative photoresist. In a case that the photoresist PR2 includes the negative photoresist, a portion of the first preliminary conductive layer CL1 that overlaps the photoresist PR2 may be removed.

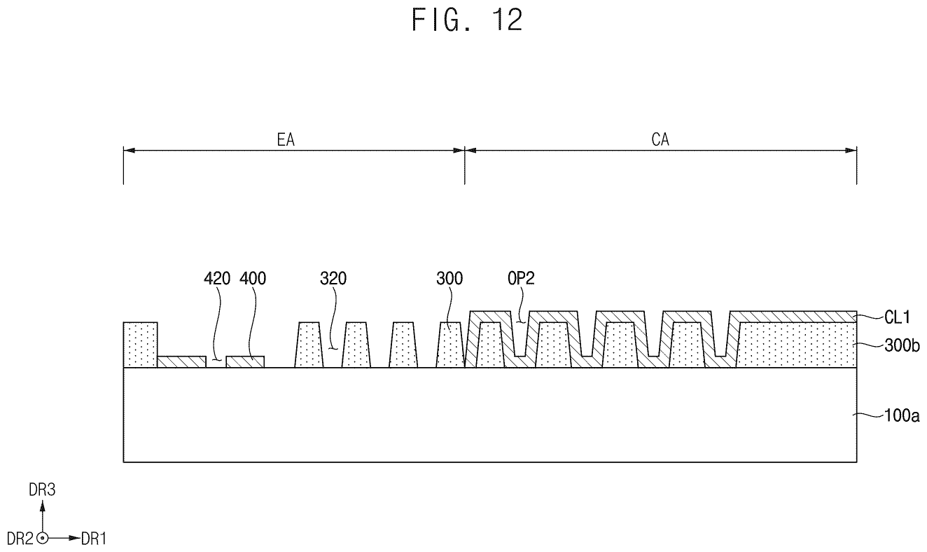

Referring to FIG. 12, a portion of the first preliminary conductive layer CL1 may be removed to form the second mask sheet 300 in which the dummy openings 320 are defined. The first preliminary conductive layer CL1 may be completely removed on the second mask sheet 300. The dummy openings 320 may correspond to the first openings (e.g., the openings OP1 of FIG. 9). That is, the dummy openings 320 may be substantially a same as the first openings.

A portion of the first preliminary conductive layer CL1 that is not removed may form the alignment portion 400. The alignment portion 400 may be formed between the second mask sheet 300 and the preliminary mask sheet 300b which the first preliminary conductive layer CL1 does not be removed. A portion of the first preliminary conductive layer CL1 forming the alignment portion 400 may be removed to define the alignment mark 420 exposing an upper surface of the preliminary frame 100a. In an embodiment, the alignment portion 400 and the second mask sheet 300 may be formed through a same process.

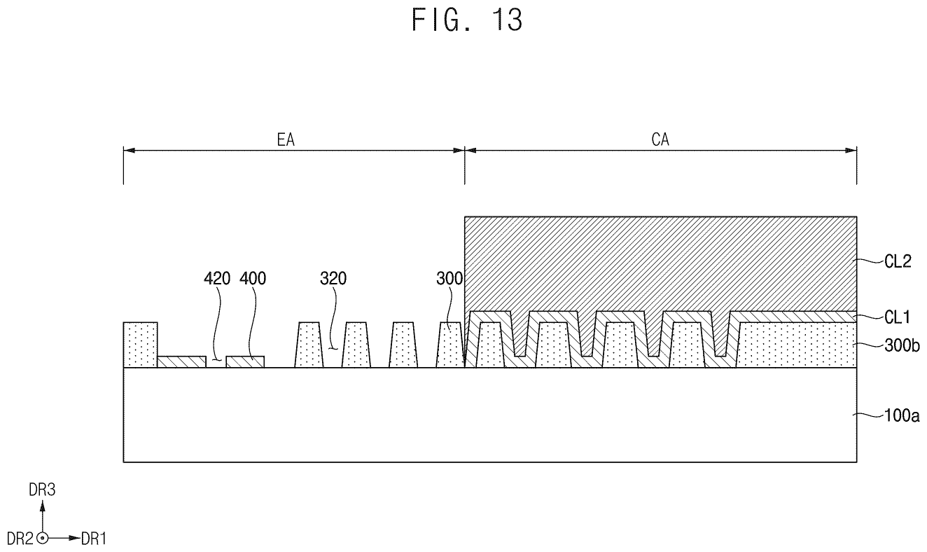

Referring to FIG. 13, a second preliminary conductive layer CL2 may be formed on the first preliminary conductive layer CL1. In an embodiment, a material forming the second preliminary conductive layer CL2 may be deposited on the first preliminary conductive layer CL1 disposed in the center area CA, for example. The second preliminary conductive layer CL2 may fill the openings OP2.

In an embodiment, the second preliminary conductive layer CL2 may be formed on the first preliminary conductive layer CL1 by electro plating. A material forming the second preliminary conductive layer CL2 may be different from a material forming the first preliminary conductive layer CL1. In an embodiment, the second preliminary conductive layer CL2 may include cobalt (Co), nickel (Ni), or the like, for example.

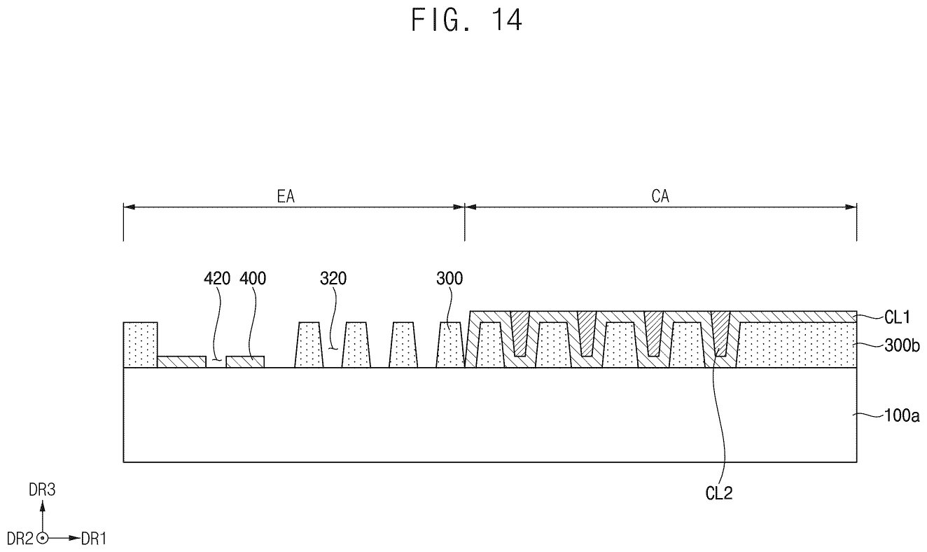

Referring to FIG. 14, a portion of the second preliminary conductive layer CL2 formed on the first preliminary conductive layer CL1 may be removed. In an embodiment, an upper portion of the second preliminary conductive layer CL2 may be removed through a flattening process, for example. The flattening process may be a chemical mechanical polishing (“CMP”) process. In an embodiment, by flattening the second preliminary conductive layer CL2, a substantially flat upper surface may be formed together with the first preliminary conductive layer CL1.

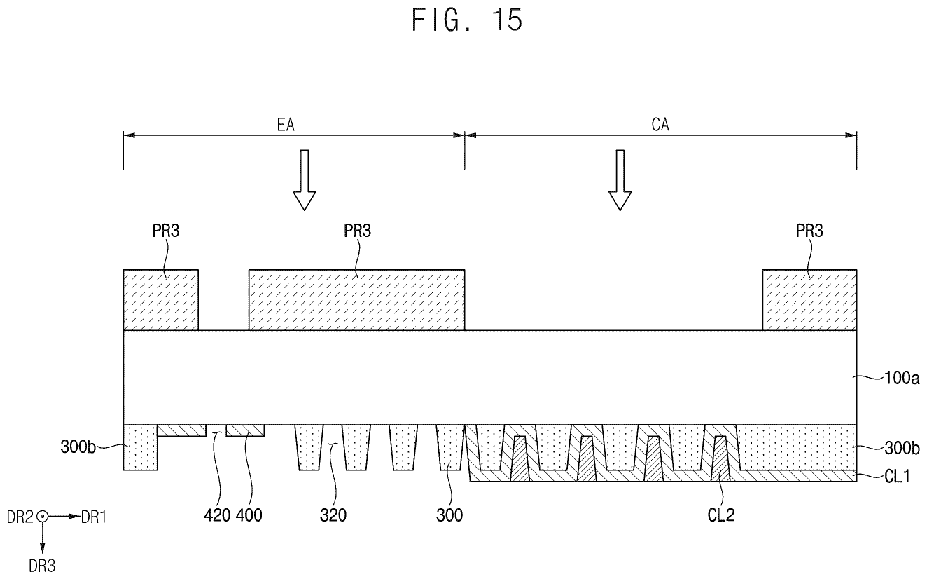

Referring to FIG. 15, a photoresist PR3 may be formed on a rear surface of the preliminary frame 100a. The photoresist PR3 may be disposed to correspond to a predetermined location of the preliminary frame 100a. After the photoresist PR3 is formed, a light may be irradiated into the rear surface of the preliminary frame 100a. As the light is irradiated, a portion of the preliminary frame 100a may be removed.

In an embodiment, the photoresist PR3 may include a positive photoresist. In a case that the photoresist PR3 includes the positive photoresist, a portion of the preliminary frame 100a that does not overlap with the photoresist PR3 may be removed. In an alternative embodiment, the photoresist PR3 may include a negative photoresist. In a case that the photoresist PR3 includes the negative photoresist, a portion overlapping with the photoresist PR3 of the preliminary frame 100a may be removed.

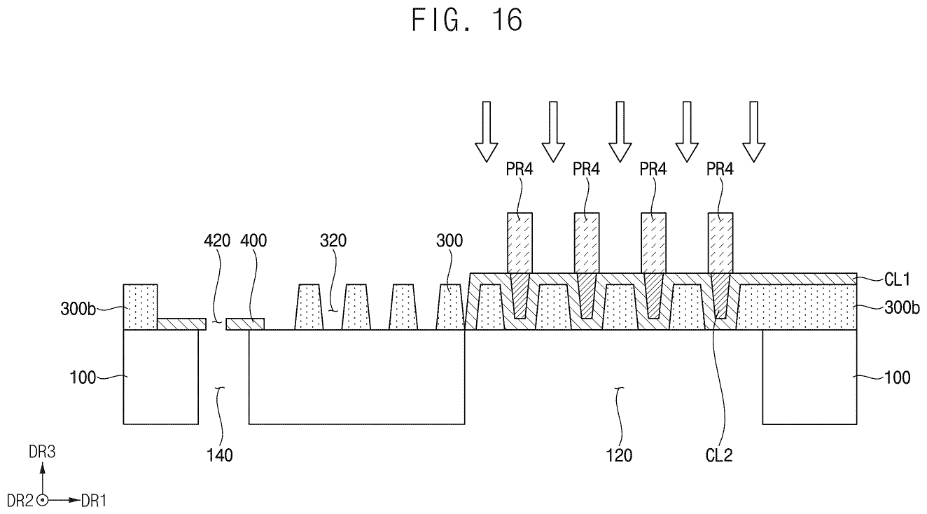

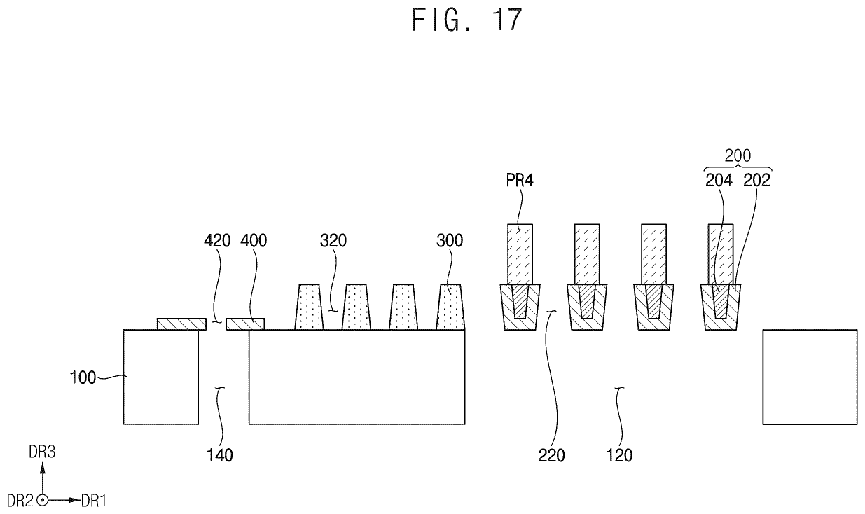

Referring to FIGS. 16 and 17, a portion of the preliminary frame 100a may be removed to form a frame 100 in which at least one of the first opening 120 and at least one of the second opening 140 are defined. The first opening 120 and the second opening 140 may penetrate the frame 100 in the third direction DR3. The second opening 140 may overlap the alignment mark 420. Accordingly, the second opening 140 and the alignment mark 420 may be connected to each other to form a single hole penetrating both the frame 100 and the alignment portion 400.

After the frame 100 is formed, a photoresist PR4 may be formed on the second preliminary conductive layer CL2. After the photoresist PR4 is formed, a light may be irradiated to remove portions of each of the first preliminary conductive layer CL1 and the preliminary mask sheet 300b that overlap the first opening 120.

In an embodiment, the photoresist PR4 may include a positive photoresist. In a case that the photoresist PR4 includes the positive photoresist, the photoresist PR4 may cover an upper surface of the second preliminary conductive layer CL2. Afterwards, the light is irradiated, and a portion of the second preliminary conductive layer CL2 that does not overlap with the photoresist PR4 may be removed.

In an alternative embodiment, the photoresist PR4 may include a negative photoresist. In a case that the photoresist PR4 includes the negative photoresist, the photoresist PR4 may cover upper surfaces of all components except the second preliminary conductive layer CL2. Afterwards, by irradiating the light, the portion of the second preliminary conductive layer CL2 that overlaps the photoresist PR4 may be removed.

After the light is irradiated, the second mask sheet 300 in which the second openings 220 are defined may be formed by removing a portion of the first preliminary conductive layer CL1 overlapping the first opening 120 and a portion of the preliminary mask sheet 300b. The deposition openings 220 may correspond to a portion where the preliminary mask sheet 300b is removed.

The mask sheet 200 may include the first conductive layer 202 and the second conductive layer 204. The first conductive layer 202 may correspond to a portion remaining after a portion of the first preliminary conductive layer CL1 is removed. The second conductive layer 204 may correspond to the second preliminary conductive layer CL2.

After removing the photoresist PR4 formed on the second conductive layer 204, the mask of FIG. 6 may be manufactured.

As described above, in the center area CA of the preliminary mask sheet 300b, as each of the first preliminary conductive layer CL1 and the second preliminary conductive layer CL2 filling the openings OP2 defined in the preliminary mask sheet 300b is removed, the first mask sheet 200 may be formed. In addition, in the edge area EA of the preliminary mask sheet 300b, a portion of the preliminary mask sheet 300b is not removed during the etching process, so that the second mask sheet 300 may be formed. Accordingly, time and cost of manufacturing process of the mask MK may be reduced.

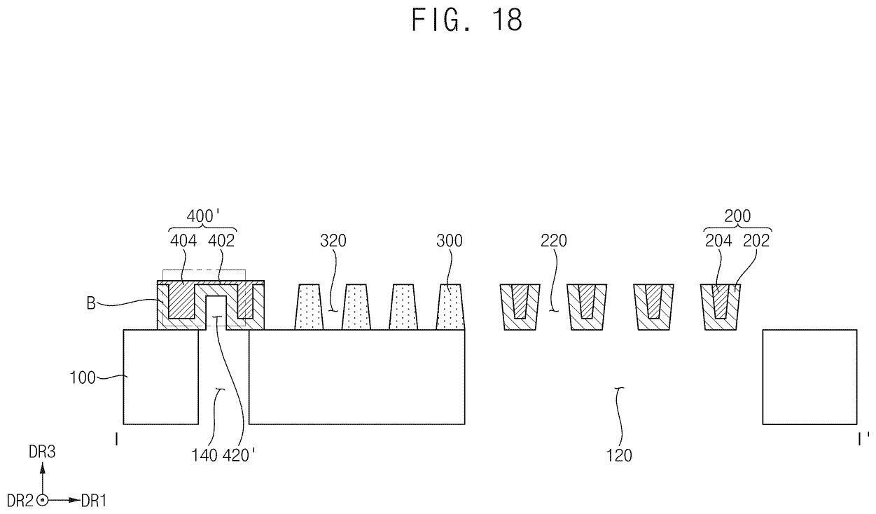

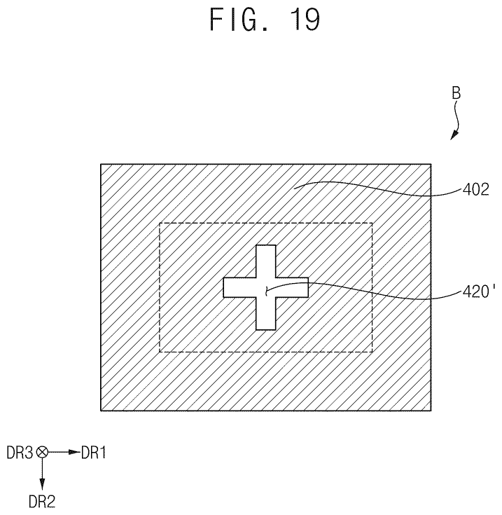

FIG. 18 is a cross-sectional view illustrating another embodiment of a cross-section taken along line I-I′ of FIG. 1. FIG. 19 is an enlarged plan view illustrating an area B of FIG. 19.

The mask of FIG. 18 is substantially a same as the mask MK of FIG. 6 except for an alignment portion 400′. Hereinafter, contents that overlap with the content described with reference to FIG. 6 will be omitted or simplified.

Referring to FIGS. 18 and 19, the mask may include an alignment portion 400′. The alignment portion 400′ may have a multi-layer structure. In an embodiment, the alignment portion 400′ may have two layers, for example. Specifically, the alignment portion 400′ may include a first layer 402 and a second layer 404. The first layer 402 and the second layer 404 may include different materials from each other.

The first layer 402 may include a same material as that of the first conductive layer 202. In an embodiment, the first layer may include titanium (Ti), titanium nitride (TiN), or the like, for example. These may be used in alone or in any combinations with each other

The second layer 404 may be disposed on the first layer 402. The second layer 404 may include a same material as that of the second conductive layer 204. In an embodiment, the second layer 404 may include cobalt (Co), nickel (Ni), or the like, for example. These may be used in alone or in any combinations with each other

An alignment mark 420′ may be defined in the alignment portion 400′. The alignment mark 420′ may be a component to align the mask when the substrate (e.g., the substrate SUB of FIG. 3) and the mask are combined with each other. The alignment mark 420′ may overlap the second opening 140. The alignment mark 420′ may be a groove in which the first layer 402 is recessed in the third direction DR3. The alignment mark 420′ may have a various shape for combining with the substrate in a plan view.

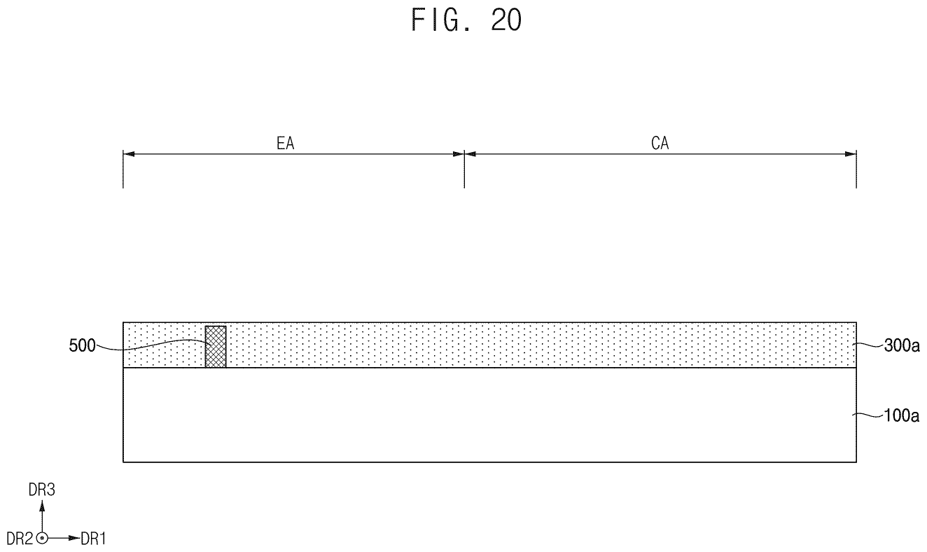

FIGS. 20, 21, 22, 23, 24, 25, and 26 are cross-sectional views illustrating another embodiment of a method of manufacturing the mask of FIG. 1.

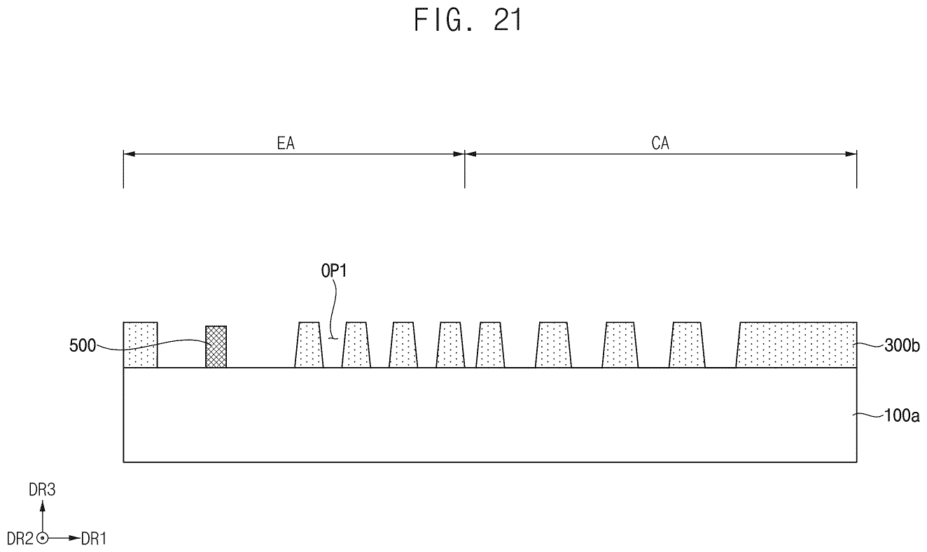

Referring to FIGS. 20 and 21, an alignment pattern 500 may be formed on the first preliminary frame 100a. In an embodiment, the alignment pattern 500 may be formed on the edge area EA of the first preliminary frame 100a, for example. The alignment pattern 500 may have a shape corresponding to a shape of the alignment mark (e.g., alignment mark 420′ in FIG. 19) in a plan view.

The preliminary mask sheet 300a may be formed on the alignment pattern 500. In an embodiment, the preliminary mask sheet 300a may cover each of the first preliminary frame 100a and the alignment pattern 500, for example. In an embodiment, the preliminary mask sheet 300a may have a substantially flat surface. In an alternative embodiment, the preliminary mask sheet 300a may form a step around the alignment pattern 500 and have a substantially uniform thickness along a profile of the alignment pattern 500.

A portion of the preliminary mask sheet 300a may be removed to form a preliminary mask sheet 300b in which the openings OP1 are defined. In an embodiment, the openings OP1 exposing a portion of an upper surface of the preliminary frame 100a and the alignment pattern 500 may be defined in the preliminary mask sheet 300b, for example. The preliminary mask sheet 300a around the alignment pattern 500 may be completely removed. A portion of the preliminary mask sheet 300a may be removed through an etching process.

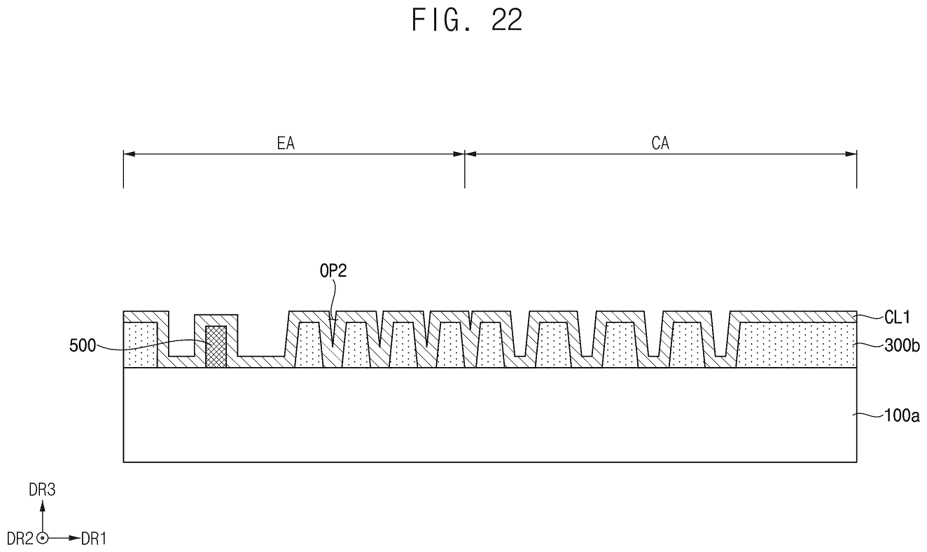

Referring to FIG. 22, the first preliminary conductive layer CL1 may be formed on the preliminary mask sheet 300b. The first preliminary conductive layer CL1 may cover upper and side surfaces of the preliminary mask sheet 300b and the alignment pattern 500. The openings OP2 corresponding to a location of the openings OP1 may be defined in the first preliminary conductive layer CL1.

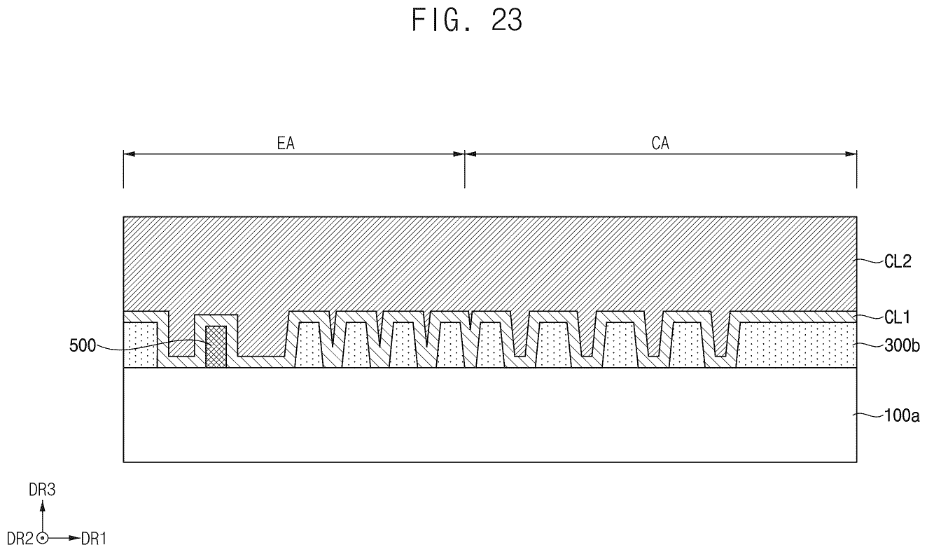

Referring to FIG. 23, the second preliminary conductive layer CL2 may be formed on the first preliminary conductive layer CL1. In an embodiment, the second preliminary conductive layer CL2 may be formed on the first preliminary conductive layer CL1 over the edge area EA and the center area CA, for example. The second preliminary conductive layer CL2 may fill the openings OP2 disposed in the edge area EA and the center area CA.

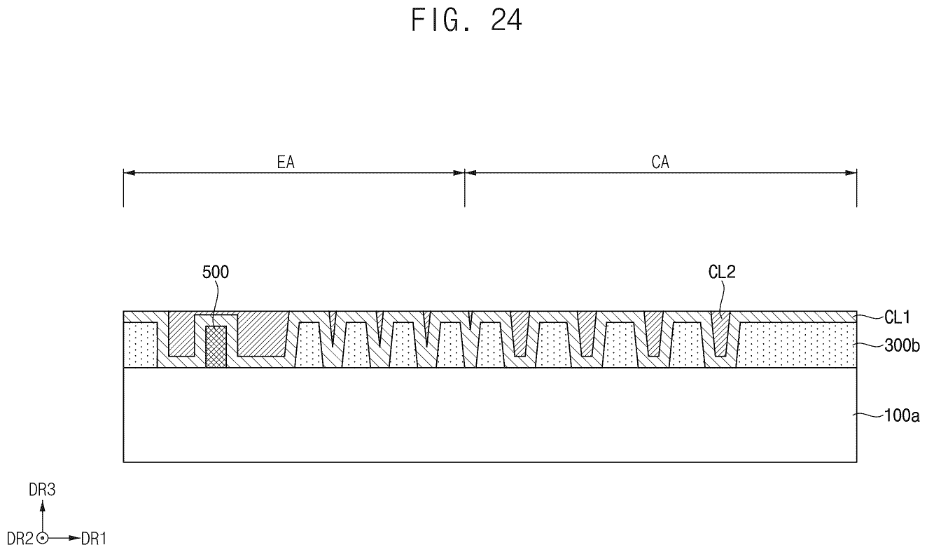

Referring to FIG. 24, a portion of the second preliminary conductive layer CL2 may be removed. In an embodiment, the second preliminary conductive layer CL2 may have a substantially flat upper surface with the first preliminary conductive layer CL1 through a flattening process, for example. The flattening process may be a CMP process.

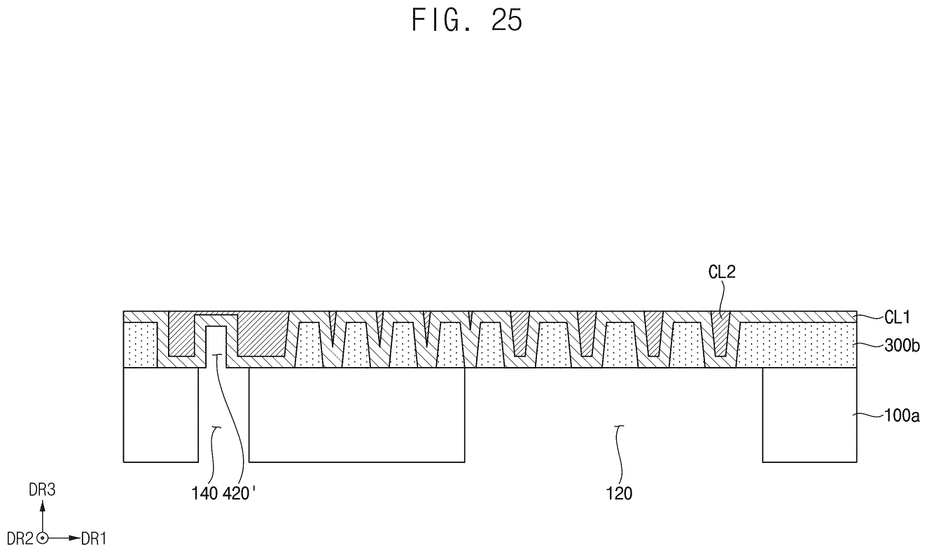

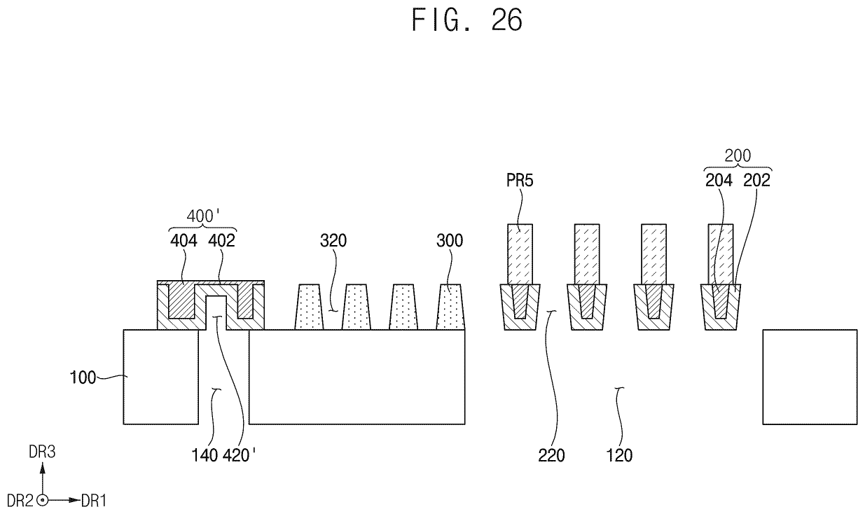

Referring to FIGS. 25 and 26, a portion of the preliminary frame 100a may be removed to form a frame 100 in which at least one of the first opening 120 and the second opening 140 are defined. The alignment mark 420′ may overlap the second opening 140.

The first mask sheet 200 may be formed as each of the preliminary mask sheet 300b, the first preliminary conductive layer CL1, and the second preliminary conductive layer CL2 which overlap the first opening 120 is removed. A process of removing a portion of each of the preliminary mask sheet 300b, the first preliminary conductive layer CL1, and the second preliminary conductive layer CL2 may be an etching process using a photoresist PR5.

The alignment portion 400′ may be formed by removing a portion of the first preliminary conductive layer CL1 and the second preliminary conductive layer CL2. Each of the first preliminary conductive layer CL1 and the second preliminary conductive layer CL2 overlapping the alignment mark 420′ may not be removed. Portions of each of the first preliminary conductive layer CL1 and the second preliminary conductive layer CL2 that are not removed may form the alignment portion 400′.

The second mask sheet 300 in which the dummy openings 320 are defined may be formed as each of the first and second preliminary conductive layers CL1 and CL2 disposed on the preliminary mask sheet 300b disposed between the alignment portion 400′ and the first mask sheet 200. In this case, removed portion of each of the first preliminary conductive layer CL1 and the second preliminary conductive layer CL2 may not overlap each of the first opening 120 and the second opening 140, respectively. In an embodiment, the alignment portion 400′ and the second mask sheet 300 may be formed through a same process.

The mask of FIG. 18 may be manufactured by removing the photoresist PR5 formed on the second conductive layer 204.

The mask and the method in the embodiments may be applied to manufacture a display device included in a computer, a notebook, a mobile phone, a smartphone, a smart pad, a portable media player (“PMP”), a personal digital assistance (“PDA”), a motion pictures expert group audio layer III (“MP3”) player, or the like.

Although the mask and the method in the embodiments have been described with reference to the drawings, the illustrated embodiments are examples, and may be modified and changed by a person having ordinary knowledge in the relevant technical field without departing from the technical spirit described in the following claims.

What is claimed is:

1. A mask comprising:
a frame in which at least one first opening defined in a center portion of the frame and at least one second opening defined in an edge portion of the frame are defined;
a first mask sheet which is disposed on the frame, and in which a plurality of deposition openings each overlapping the first opening is defined; and
a second mask sheet surrounding at least a portion of the first mask sheet on the frame, and including a different material from a material of the first mask sheet.

2. The mask of claim 1, wherein the second mask sheet directly contacts the edge portion of the frame.

3. The mask of claim 1, wherein the first mask sheet includes a magnetic material.

4. The mask of claim 1, wherein the first mask sheet includes:
a first conductive layer; and
a second conductive layer disposed on the first conductive layer.

5. The mask of claim 4, wherein the first conductive layer includes at least one of a titanium (Ti) and a titanium nitride (TiN), and
the second conductive layer includes at least one of cobalt (Co) and a nickel (Ni).

6. The mask of claim 4, further comprising:
an alignment portion disposed on the frame, adjacent to the second mask sheet, and in which an alignment mark is defined,
wherein the alignment portion includes a same material as a material of the first conductive layer.

7. The mask of claim 6, wherein the alignment mark overlaps the second opening.

8. The mask of claim 6, wherein the alignment portion includes:
a first layer corresponding to the first conductive layer; and
a second layer disposed on the first layer and corresponding to the second conductive layer, and
wherein the first layer includes a same material as the material of the first conductive layer, and the second layer includes a same material as a material of the second conductive layer.

9. The mask of claim 6, wherein the alignment portion is spaced apart from the first mask sheet.

10. The mask of claim 1, wherein a portion of the first mask sheet disposed between two deposition openings adjacent to each other among the plurality of deposition openings has an inverse tapered shape in a cross-sectional view.

11. The mask of claim 1, wherein a plurality of dummy openings penetrating the second mask sheet in a thickness direction is defined in the second mask sheet.

12. The mask of claim 10, wherein a portion of the second mask sheet disposed between two dummy openings adjacent to each other among a plurality of dummy openings has a tapered shape in the cross-sectional view.

13. A method of manufacturing a mask, the method comprising:
forming a preliminary mask sheet on a preliminary frame including a center area and an edge area adjacent to the center area;
forming a first preliminary conductive layer on the preliminary mask sheet;
forming a second preliminary conductive layer on at least a portion of the first preliminary conductive layer;
forming a frame in which at least one first opening defined in the center area and at least one second opening defined in the edge area are defined by removing a portion of the preliminary frame;
forming a first mask sheet in which a plurality of deposition openings area is defined by removing a portion of each of the first preliminary conductive layer and the second preliminary conductive layer in the center area; and
forming a second mask sheet in which a plurality of dummy openings is defined by removing a portion of the first preliminary conductive layer in the edge area.

14. The method of claim 13, further comprising:
forming an alignment portion in which an alignment mark is defined by removing a portion of the first preliminary conductive layer in the edge area.

15. The method of claim 14, wherein the forming the alignment portion and the forming the second mask sheet are performed by a same process.

16. The method of claim 13, further comprising:
forming an alignment pattern in the edge area of the preliminary frame; and
covering the alignment pattern by the preliminary mask sheet,
wherein the forming the alignment pattern and the covering the alignment pattern are performed before the forming the preliminary mask sheet.

17. The method of claim 16, wherein the second preliminary conductive layer overlaps the alignment pattern in a plan view.

18. The method of claim 16, further comprising:
removing the alignment pattern; and
forming an alignment portion in which an alignment mark is defined in an area corresponding to the alignment pattern by removing each of the first preliminary conductive layer and the second preliminary conductive layer.

19. The method of claim 18, wherein forming the removing the alignment pattern and the forming the frame are performed simultaneously.

20. The method of claim 13, wherein the forming the second preliminary conductive layer includes:
flattening the second preliminary conductive layer so that an upper surface of the second preliminary conductive layer is substantially flat and aligned with an upper surface of the first preliminary conductive layer.
